(19) United States
(12) Patent Application Publication
(10) Pub. No.: US 2024/0297624 A1
(43) Pub. Date: Sep. 5, 2024

(54) AMPLIFIER CIRCUIT ASSEMBLY, A RADIO FREQUENCY MODULE AND A MOBILE DEVICE INCLUDING THE SAME

(71) Applicant: Skyworks Solutions, Inc., Irvine, CA (US)

(72) Inventors: Roman Zbigniew Arkiszewski, Oak Ridge, NC (US); Jeffrey Gordon Strahler, Greensboro, NC (US)

(21) Appl. No.: 18/593,594

(22) Filed: Mar. 1, 2024

Related U.S. Application Data
(60) Provisional application No. 63/449,759, filed on Mar. 3, 2023.

(51) Int. Cl. H03F 3/24; H03F 1/02; H04B 1/401

(52) U.S. Cl. CPC H03F 3/245; H03F 1/0233; H03F 2200/451; H04B 1/401

(57) ABSTRACT

An amplifier circuit assembly has a power supply that generates a supply voltage that changes based on a radio frequency signal and powers a cascade amplifier module. The amplifier modules amplifies the radio frequency signal and includes a first amplifier stage and a second amplifier stage configured to operate in respective operation modes. The first and second amplifier stages have first and second supply nodes floated from a ground by first and second adjustable capacitances, respectively. A switch connects or disconnects the first supply node and the second supply node depending on the respective operation modes.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the invention relate to electronic systems, and in particular, to power amplifiers for use in radio frequency (RF) electronics.

### Description of the Related Technology

Power amplifiers are used in radio frequency (RF) communication systems to amplify RF signals for transmission via antennas. It is important to manage the power of RF signal transmissions to prolong battery life and/or provide a suitable transmit power level.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 410 MHz to about 7.125 GHz for certain communications standards.

### SUMMARY

In some aspects, the techniques described herein relate to an amplifier circuit assembly including: a power supply module configured to generate a supply voltage that changes based on a radio frequency signal; a cascade amplifier module configured to amplify the radio frequency signal when powered at least by the supply voltage, the cascade amplifier module including a first amplifier stage and a second amplifier stage configured to operate in respective operation modes, the first amplifier stage having a first supply node floated from a ground by a first adjustable capacitance, the second amplifier stage having a second supply node floated from the ground by a second adjustable capacitance, the supply voltage being applied to the second supply node; and a switch configured to connect or disconnect the first supply node and the second supply node depending on the respective operation modes of the first amplifier stage and the second amplifier stage.

In some aspects, the techniques described herein relate to an amplifier circuit assembly wherein each of the respective operation modes is an average power tracking mode or an envelope tracking mode.

In some aspects, the techniques described herein relate to an amplifier circuit assembly wherein the power supply module is configured to generate the supply voltage depending on an operation mode of the second amplifier stage.

In some aspects, the techniques described herein relate to an amplifier circuit assembly wherein the switch is configured to be closed when the first amplifier stage and the second amplifier stage are operating in a same operation mode such that the supply voltage is applied to the first supply node.

In some aspects, the techniques described herein relate to an amplifier circuit assembly wherein the switch is configured to be opened when the first amplifier stage and the second amplifier stage are operating in different operation modes or when the first amplifier stage and the second amplifier stage are operating in a same operation mode separately.

In some aspects, the techniques described herein relate to an amplifier circuit assembly further including an additional power supply that is configured to provide a constant supply voltage to the first supply node.

In some aspects, the techniques described herein relate to an amplifier circuit assembly wherein the first adjustable capacitance is adjusted to be reduced when the first amplifier stage is operating in the envelope tracking mode.

In some aspects, the techniques described herein relate to an amplifier circuit assembly wherein the first supply node is connected to the ground via a first default capacitor connected to an additional capacitor in parallel, and the first adjustable capacitance is adjusted by switching a first capacitor switch disposed between the additional capacitor and the ground.

In some aspects, the techniques described herein relate to an amplifier circuit assembly wherein the second adjustable capacitance is adjusted to be reduced when the second amplifier stage is operating in the envelope tracking mode.

In some aspects, the techniques described herein relate to an amplifier circuit assembly wherein the second supply node is connected to the ground via a second default capacitor connected to an additional capacitor in parallel, and the second adjustable capacitance is adjusted by switching a second capacitor switch disposed between the additional capacitor and the ground.

In some aspects, the techniques described herein relate to a radio frequency module including: a packaging substrate configured to receive a plurality of components; and an amplifier circuit assembly implemented on the packaging substrate, the amplifier circuit assembly including a power supply module configured to generate a supply voltage that changes based on a radio frequency signal, a cascade amplifier module configured to amplify the radio frequency signal when powered at least by the supply voltage, the cascade amplifier module including a first amplifier stage and a second amplifier stage configured to operate in respective operation modes, the first amplifier stage having a first supply node floated from a ground by a first adjustable capacitance, the second amplifier stage having a second supply node floated from the ground by a second adjustable capacitance, the supply voltage being applied to the second supply node, and a switch configured to connect or disconnect the first supply node and the second supply node depending on the respective operation modes of the first amplifier stage and the second amplifier stage.

In some aspects, the techniques described herein relate to a radio frequency module wherein the radio frequency module is a front-end module.

In some aspects, the techniques described herein relate to a radio frequency module wherein each of the respective operation modes is an average power tracking mode or an envelope tracking mode.

In some aspects, the techniques described herein relate to a radio frequency module wherein the power supply module is configured to generate the supply voltage depending on an operation mode of the second amplifier stage.

In some aspects, the techniques described herein relate to a radio frequency module wherein the switch is configured to be closed when the first amplifier stage and the second amplifier stage are operating in a same operation mode such that the supply voltage is applied to the first supply node.

In some aspects, the techniques described herein relate to a radio frequency module wherein the switch is configured to be opened when the first amplifier stage and the second amplifier stage are operating in different operation modes or when the first amplifier stage and the second amplifier stage are operating in a same operation mode separately.

In some aspects, the techniques described herein relate to a radio frequency module further including an additional power supply that is configured to provide a constant supply voltage to the first supply node.

In some aspects, the techniques described herein relate to a radio frequency module wherein the first adjustable capacitance is adjusted to be reduced when the first amplifier stage is operating in the envelope tracking mode.

In some aspects, the techniques described herein relate to a radio frequency module wherein the first supply node is connected to the ground via a first default capacitor connected to an additional capacitor in parallel, and the first adjustable capacitance is adjusted by switching a first capacitor switch disposed between the additional capacitor and the ground.

In some aspects, the techniques described herein relate to a radio frequency module wherein the second adjustable capacitance is adjusted to be reduced when the second amplifier stage is operating in the envelope tracking mode.

In some aspects, the techniques described herein relate to a radio frequency module wherein the second supply node is connected to the ground via a second default capacitor connected to an additional capacitor in parallel, and the second adjustable capacitance is adjusted by switching a second capacitor switch disposed between the additional capacitor and the ground.

In some aspects, the techniques described herein relate to a mobile device including: a transceiver configured to generate a radio frequency signal; and a front end system including an amplifier circuit assembly, the amplifier circuit assembly including a power supply module configured to generate a supply voltage that changes based on the radio frequency signal, a cascade amplifier module configured to amplify the radio frequency signal when powered at least by the supply voltage, the cascade amplifier module including a first amplifier stage and a second amplifier stage configured to operate in respective operation modes, the first amplifier stage having a first supply node floated from a ground by a first adjustable capacitance, the second amplifier stage having a second supply node floated from the ground by a second adjustable capacitance, the supply voltage being applied to the second supply node, and a switch configured to connect or disconnect the first supply node and the second supply node depending on the respective operation modes of the first amplifier stage and the second amplifier stage.

In some aspects, the techniques described herein relate to a mobile device wherein each of the respective operation modes is an average power tracking mode or an envelope tracking mode.

In some aspects, the techniques described herein relate to a mobile device wherein the power supply module is configured to generate the supply voltage depending on an operation mode of the second amplifier stage.

In some aspects, the techniques described herein relate to a mobile device wherein the switch is configured to be closed when the first amplifier stage and the second amplifier stage are operating in a same operation mode such that the supply voltage is applied to the first supply node.

In some aspects, the techniques described herein relate to a mobile device wherein the switch is configured to be opened when the first amplifier stage and the second amplifier stage are operating in different operation modes or when the first amplifier stage and the second amplifier stage are operating in a same operation mode separately.

In some aspects, the techniques described herein relate to a mobile device further including an additional power supply that is configured to provide a constant supply voltage to the first supply node.

In some aspects, the techniques described herein relate to a mobile device wherein the first adjustable capacitance is adjusted to be reduced when the first amplifier stage is operating in the envelope tracking mode.

In some aspects, the techniques described herein relate to a mobile device wherein the first supply node is connected to the ground via a first default capacitor connected to an additional capacitor in parallel, and the first adjustable capacitance is adjusted by switching a first capacitor switch disposed between the additional capacitor and the ground.

In some aspects, the techniques described herein relate to a mobile device wherein the second adjustable capacitance is adjusted to be reduced when the second amplifier stage is operating in the envelope tracking mode.

In some aspects, the techniques described herein relate to a mobile device wherein the second supply node is connected to the ground via a second default capacitor connected to an additional capacitor in parallel, and the second adjustable capacitance is adjusted by switching a second capacitor switch disposed between the additional capacitor and the ground.

### BRIEF DESCRIPTION OF THE DRAWINGS

FIG. 1 is a schematic diagram of one embodiment of a mobile device.

FIG. 2 is a detailed block diagram of one example of a power amplifier system.

FIGS. 3A-3E show non-limiting examples of power amplifiers.

FIG. 4 is a schematic diagram of an example of an amplifier circuit assembly with an APT mode capacitor.

FIG. 5 is a schematic diagram of an example of an amplifier circuit assembly with an additional capacitor.

FIG. 6 is a schematic diagram of an example of an amplifier circuit assembly with a capacitor switch.

FIG. 7 is a schematic diagram of an example of an amplifier circuit assembly according to an embodiment of the present disclosure.

FIGS. 8A-8C are example of waveforms for power amplifiers operating in a fixed supply voltage mode, an average power tracking (APT) mode, and an envelope tracking (ET) mode.

FIGS. 9A-9B are schematic diagrams of an envelope tracking system according to one embodiment.

FIG. 10 is a schematic diagram of an envelope tracking system according to another embodiment.

FIG. 11A is a schematic diagram of one embodiment of a packaged module.

FIG. 11B is a schematic diagram of a cross-section of the packaged module of FIG. 11A taken along the lines 11B-11B.

FIG. 12 is a schematic diagram of one embodiment of a phone board.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

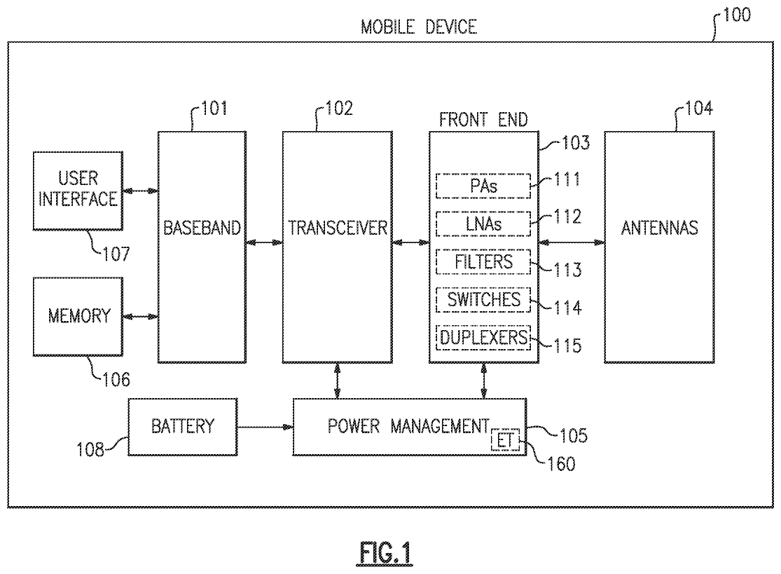

FIG. 1 is a schematic diagram of one example of a mobile device 100. The mobile device 100 includes a baseband system 101, a transceiver 102, a front end system 103, antennas 104, a power management system 105, a memory 106, a user interface 107, and a battery 108.

The mobile device 100 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 102 generates RF signals for transmission and processes incoming RF signals received from the antennas 104. It will be understood that various functionalities associated with the transmission and receiving of RF signals can be achieved by one or more components that are collectively represented in FIG. 1 as the transceiver 102. In one example, separate components (for instance, separate circuits or dies) can be provided for handling certain types of RF signals.

The front end system 103 aids in conditioning signals transmitted to and/or received from the antennas 104. In the illustrated embodiment, the front end system 103 includes power amplifiers (PAs) 111, low noise amplifiers (LNAs) 112, filters 113, switches 1014, and duplexers 115. However, other implementations are possible.

For example, the front end system 103 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 100 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band and/or in different bands.

The antennas 104 can include antennas used for a wide variety of types of communications. For example, the antennas 104 can include antennas associated transmitting and/or receiving signals associated with a wide variety of frequencies and communications standards.

In certain implementations, the antennas 104 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 100 can operate with beamforming in certain implementations. For example, the front end system 103 can include phase shifters having variable phase controlled by the transceiver 102. Additionally, the phase shifters are controlled to provide beam formation and directivity for transmission and/or reception of signals using the antennas 104. For example, in the context of signal transmission, the phases of the transmit signals provided to the antennas 104 are controlled such that radiated signals from the antennas 104 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 1004 from a particular direction. In certain implementations, the antennas 104 include one or more arrays of antenna elements to enhance beamforming.

The baseband system 101 is coupled to the user interface 107 to facilitate processing of various user input and output (I/O), such as voice and data. The baseband system 101 provides the transceiver 102 with digital representations of transmit signals, which the transceiver 102 processes to generate RF signals for transmission. The baseband system 101 also processes digital representations of received signals provided by the transceiver 102. As shown in FIG. 1, the baseband system 101 is coupled to the memory 106 of facilitate operation of the mobile device 100.

The memory 106 can be used for a wide variety of purposes, such as storing data and/or instructions to facilitate the operation of the mobile device 100 and/or to provide storage of user information.

The power management system 105 provides a number of power management functions of the mobile device 100. The power management system 105 of FIG. 1 includes an envelope tracker 160. As shown in FIG. 1, the power management system 105 receives a battery voltage form the battery 108. The battery 108 can be any suitable battery for use in the mobile device 100, including, for example, a lithium-ion battery.

The mobile device 100 of FIG. 1 illustrates one example of an RF communication system that can include power amplifier(s) implemented in accordance with one or more features of the present disclosure. However, the teachings herein are applicable to RF communication systems implemented in a wide variety of ways.

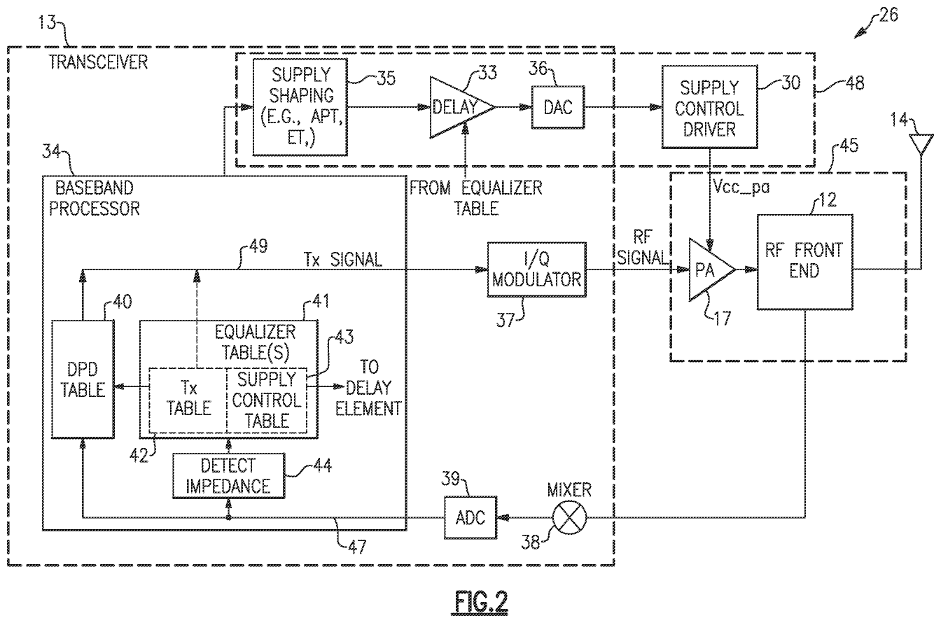

FIG. 2 is a detailed block diagram of one example of a power amplifier system 26. For example, the power amplifier system 26 may be incorporated into the mobile device 100 of FIG. 1. The illustrated power amplifier system 26 includes an RF front end 12, an antenna 14, a battery 21, a supply control driver 30, a power amplifier 17, and a transceiver 13. The illustrated transceiver 13 includes a baseband processor 34, a supplying shaping block or circuit 35, a delay component 33, a digital-to-analog converter (DAC) 36, a quadrature (I/Q) modulator 37, a mixer 38, and an analog-to-digital converter (ADC) 39. The supply shaping block 35, delay component 33, DAC 36, and supply control driver 30 together form a supply shaping branch 48.

The baseband processor 34 can be used to generate an I signal and a Q signal, which correspond to signal components of a sinusoidal wave or signal of a desired amplitude, frequency, and phase. For example, the I signal can be used to represent an in-phase component of the sinusoidal wave and the Q signal can be used to represent a quadrature component of the sinusoidal wave, which can be an equivalent representation of the sinusoidal wave. In certain implementations, the I and Q signals can be provided to the I/Q modulator 37 in a digital format. The baseband processor 34 can be any suitable processor configured to process a baseband signal. For instance, the baseband processor 34 can include a digital signal processor, a microprocessor, a programmable core, or any combination thereof. Moreover, in some implementations, two or more baseband processors 34 can be included in the power amplifier system 26.

The I/Q modulator 37 can be configured to receive the I and Q signals from the baseband processor 34 and to process the I and Q signals to generate an RF signal. For example, the I/Q modulator 37 can include DACs configured to convert the I and Q signals into an analog format, mixers for upconverting the I and Q signals to radio frequency, and a signal combiner for combining the upconverted I and Q signals into an RF signal suitable for amplification by the power amplifier 17. In certain implementations, the I/Q modulator 37 can include one or more filters configured to filter frequency content of signals processed therein.

The supply shaping block 35 can be used to convert an envelope or amplitude signal associated with the I and Q signals into a shaped power supply control signal, such as an average power tracking (APT) signal or an envelope tracking (ET) signal, depending on the embodiment. Shaping the envelope signal from the baseband processor 34 can aid in enhancing performance of the power amplifier system 26. In certain implementations, such as where the supplying shaping block is configured to implement an envelope tracking function, the supply shaping block 35 is a digital circuit configured to generate a digital shaped envelope signal, and the DAC 36 is used to convert the digital shaped envelope signal into an analog shaped envelope signal suitable for use by the supply control driver 30. However, in other implementations, the DAC 36 can be omitted in favor of providing the supply control driver 30 with a digital envelope signal to aid the supply control driver 30 in further processing of the envelope signal.

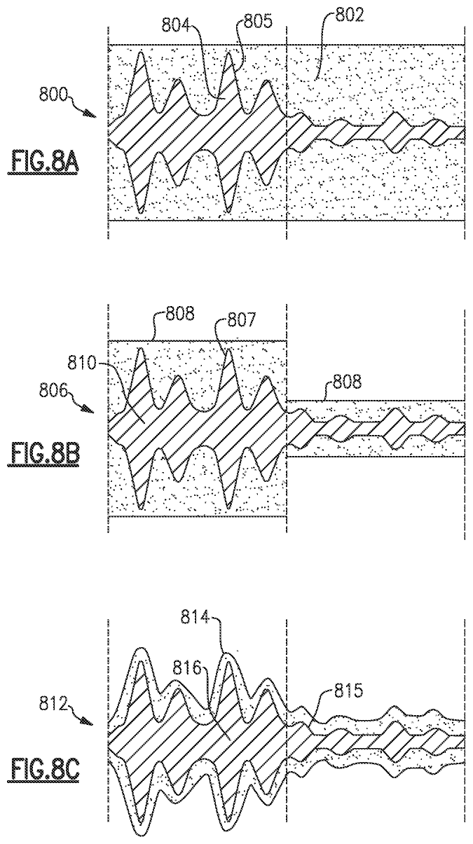

The supply control driver 30 can receive the supply control signal (e.g., an analog shaped envelope signal or APT signal) from the transceiver 13 and a battery voltage VBATT from the battery 21, and can use the supply control signal to generate a power amplifier supply voltage VCC_PA for the power amplifier 17 that changes in relation to the transmit signal. The power amplifier 17 can receive the RF transmit signal from the I/Q modulator 37 of the transceiver 13, and can provide an amplified RF signal to the antenna 14 through the RF front end 12. In other cases, a fixed power amplifier supply voltage VCC_PA is provided to the power amplifier 17. In some such embodiments, one or more of the supply shaping block 35, DAC 36, and supply control driver 30 may not be included. Exemplary waveforms of power amplifier supply voltage VCC_PA and corresponding RF transmit signals are shown in FIGS. 8A, 8B, and 8C for fixed supply, APT, and ET power supply control operations, respectively. In some embodiments, the power amplifier system 26 is capable of performing two or more supply control techniques. For instance, the power amplifier system 26 allows for selection (e.g., via firmware programming or other appropriate mechanism) of two or more of ET, APT, and fixed power supply control modes. In such cases, the baseband processor or other appropriate controller or processor may instruct the supply shaping block 35 to enter into the appropriate selected mode.

The delay component 33 implements a selectable delay in the supply control path. As will be described in further detail, this can be useful in some cases for compensating for non-linearities and/or other potential sources of signal degradation. The illustrated delay component is shown in the digital domain as part of the transceiver 13, and may comprise a FIFO or other type of memory-based delay element. However, the delay component 33 can be implemented in any appropriate fashion, and in other embodiments may be integrated as part of the supply shaping block 35, or may be implemented in the analog domain, after the DAC 36, for example.

The RF front end 12 receives the output of the power amplifier 17, and can include a variety of components including one or more duplexers, switches (e.g., formed in an antenna switch module), directional couplers, and the like.

The directional coupler (not shown) within the RF front end 12 can be a dual directional coupler or other appropriate coupler or other device capable of providing a sensed output signal to the mixer 38. According to certain embodiments, including the illustrated embodiment, the directional coupler is capable of providing both incident and reflected signals (e.g., forward and reverse power) to the mixer 38. For instance, the directional coupler can have at least four ports, which may include an input port configured to receive signals generated by the power amplifier 17, an output port coupled to the antenna 14, a first measurement port configured to provide forward power to the mixer 38, and a second measurement port configured to provide reverse power to the mixer 38.

The mixer 38 can multiply the sensed output signal by a reference signal of a controlled frequency (not illustrated in FIG. 2) so as to downshift the frequency spectrum of the sensed output signal. The downshifted signal can be provided to the ADC 39, which can convert the downshifted signal to a feedback signal 47 in a digital format suitable for processing by the baseband processor 34. As will be discussed in further detail, by including a feedback path between the output of the power amplifier 17 and an input of the baseband processor 34, the baseband processor 34 can be configured to dynamically adjust the I and Q signals and/or power control signal associated with the I and Q signals to optimize the operation of the power amplifier system 26. For example, configuring the power amplifier system 26 in this manner can aid in controlling the power added efficiency (PAE) and/or linearity of the power amplifier 32. The mixer 38, ADC 39 and/or other appropriate componentry may generally perform a quadrature (I/Q) demodulation function in some embodiments.

Although the power amplifier system 26 is illustrated as include a single power amplifier, the teachings herein are applicable to power amplifier systems including multiple power amplifiers, including, for example, multi-mode and/or multi-mode power amplifier systems.

Additionally, although FIG. 2 illustrates a particular configuration of a transceiver, other configurations are possible, including for example, configurations in which the transceiver 13 includes more or fewer components and/or a different arrangement of components.

As shown the baseband processor 34 can include a digital pre-distortion (DPD) table 40, an equalizer table 41, and a complex impedance detector 44. The DPT table 40 may be stored in a non-volatile memory (e.g., flash memory, read only memory (ROM), etc.) of the transceiver 34 that is accessible by the baseband processor 34. According to some embodiments, the baseband processor 34 accesses entries in the DPD table 40 to aid in linearizing the power amplifier 17. For instance, the baseband processor 34 selects appropriate entries in the DPD table 40 based on the sensed feedback signal 47, and adjusts the transmit signal accordingly, prior to outputting the transmit signal to the I/Q modulator 37. For example, DPD can be used to compensate for certain nonlinear effects of the power amplifier 17, including, for example, signal constellation distortion and/or signal spectrum spreading. According to certain embodiments including the illustrated embodiment, the DPD table 40 implements memoryless DPD, e.g., where the current output of the DPD corrected transmit signal depends only on the current input.

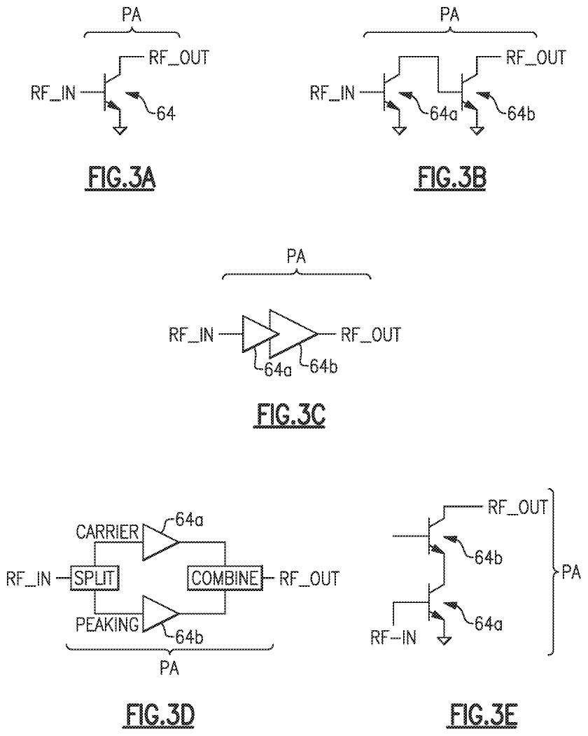

For the purpose of description, it will be understood that the PA of FIG. 2 can be implemented in a number of ways. FIGS. 3A-3E show non-limiting examples of how such a PA can implemented.

FIG. 3A shows an example PA having an amplifying transistor 64, where an input RF signal (RF_in) is provided to a base of the transistor 64, and an amplified RF signal (RF_out) is output through a collector of the transistor 64.

FIG. 3B shows an example PA having a plurality of amplifying transistors (e.g., 64 a, 64 b) arranged in stages. An input RF signal (RF_in) is provided to a base of the first transistor 64 a, and an amplified RF signal from the first transistor 64 a is output through its collector. The amplified RF signal from the first transistor 64 a is provided to a base of the second transistor 64 b, and an amplified RF signal from the second transistor 64 b is output through its collector to thereby yield an output RF signal (RF_out) of the PA.

In some embodiments, the foregoing example PA configuration of FIG. 3B can be depicted as two or more stages as shown in FIG. 3C. The first stage 64 a can be configured as, for example, a driver stage; and the second stage 64 b can be configured as, for example, an output stage.

FIG. 3D shows that in some embodiments, a PA can be configured as a Doherty PA. Such a Doherty PA can include amplifying transistors 64 a, 64 b configured to provide carrier amplification and peaking amplification of an input RF signal (RF_in) to yield an amplified output RF signal (RF_out). The input RF signal can be split into the carrier portion and the peaking portion by a splitter. The amplified carrier and peaking signals can be combined to yield the output RF signal by a combiner.

FIG. 3E shows that in some embodiments, a PA can be implemented in a cascode configuration. An input RF signal (RF_in) can be provided to a base of the first amplifying transistor 64 a operated as a common emitter device. The output of the first amplifying transistor 64 a can be provided through its collector and be provided to an emitter of the second amplifying transistor 64 b operated as a common base device. The output of the second amplifying transistor 64 b can be provided through its collector so as to yield an amplified output RF signal (RF_out) of the PA.

In the various examples of FIGS. 3A-3E, the amplifying transistors are described as bipolar junction transistors (BJTs) such as heterojunction bipolar transistors (HBTs). It will be understood that one or more features of the present disclosure can also be implemented in or with other types of transistors such as field-effect transistors (FETs).

Envelope tracking (ET) is one of the most suitable solutions when considering both linearity and efficiency. ET techniques improve the efficiency by modulating the drain voltage of the PA according to the envelope of the input signal. Alternatively, average power tracking (APT) is also a widely-implemented approach to reduce unnecessary power consumption in RF PAs. Despite of various advantages of ET, such as improved linearity, APT still has its own advantage in terms of efficiency on the PA system in particular when it comes with a low output voltage. APT offers acceptable results for low output power and ET improves efficiency at high output power and high PAPR. Thus, it would be beneficial to selectively determine a voltage supplying mode (APT or ET) for a PA system based on the level of output power.

Committing to operating a PA system in either APT or ET modes of operation early in the product definition process is rarely done due to various uncertainties in that development stage. Instead, supporting the highest levels of performance during both modes of operation is frequently specified to be desirable.

It is challenging to design a power amplifier that performs well in both APT and ET modes of operation due to conflicting requirements for the ET modulator load and the PA supply needed for APT operation. This becomes even more challenging to accomplish while supporting 5G NR carriers with wide bandwidth modulation.

Previous solutions attempted to allow both ET and APT operation by switching in a large APT mode capacitor which was placed near the ET modulator and controlled by an ET modulator switch.

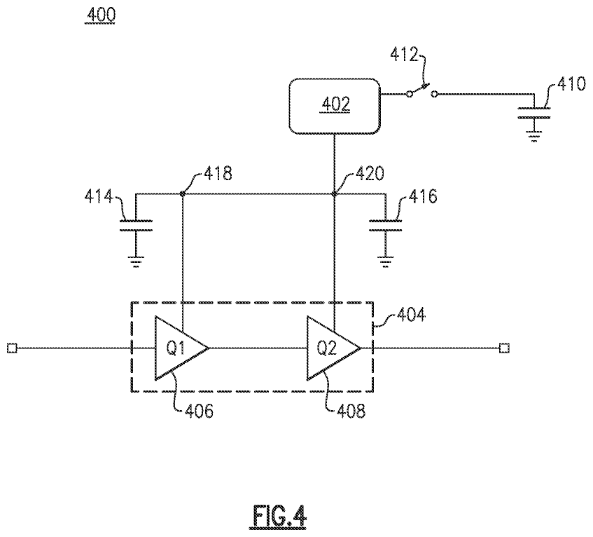

FIG. 4 is a schematic diagram of an example of an amplifier circuit assembly 400 with an APT mode capacitor 410. In FIG. 4, the amplifier circuit assembly 400 includes a power supply module 402, a cascade amplifier module 404, and an APT mode capacitor 410.

The power supply module 402 is configured to generate a supply voltage that changes on the basis of a radio frequency signal. For example, the supply voltage may be either envelope tracking (ET) signal or an average power tracking (APT) signal. The power supply module 402 may include a switch 412 configured to connect with the APT mode capacitor 410. The APT mode capacitor 410 may be disposed between the switch 412 and a ground.

The cascade amplifier module 404 may include a first amplifier stage 406 and a second amplifier stage 408 connected to the first amplifier stage 406 in series. The first amplifier stage 406 may have a first supply node 418 connected to a ground through a first capacitor 414. The second amplifier stage 408 may have a second supply node 420 connected to the ground through a second capacitor 416. The second supply node 420 may be configured to receive the supply voltage from the power supply module. The first supply node 418 and the second supply node 420 may be electrically connected to each other.

The switch 412 may be configured to be closed when the first amplifier stage 406 and the second amplifier stage 408 are operating in APT modes. This works reasonably well for narrow bandwidth signals, but failed for larger bandwidth signals due to the parasitic inductance of the devices and traces between the amplifier circuit assembly 404 and APT mode capacitor 410. This parasitic inductance may reduce the effective capacitance seen by the amplifier circuit assembly 404. An approach such as this would not be suitable for the bandwidths associated with 5G NR waveforms while operating in APT mode.

To achieve a higher effective APT mode capacitance for wide bandwidth signals an additional large capacitor can be placed at the Vcc node (second supply node 420) of the second amplifier stage 408.

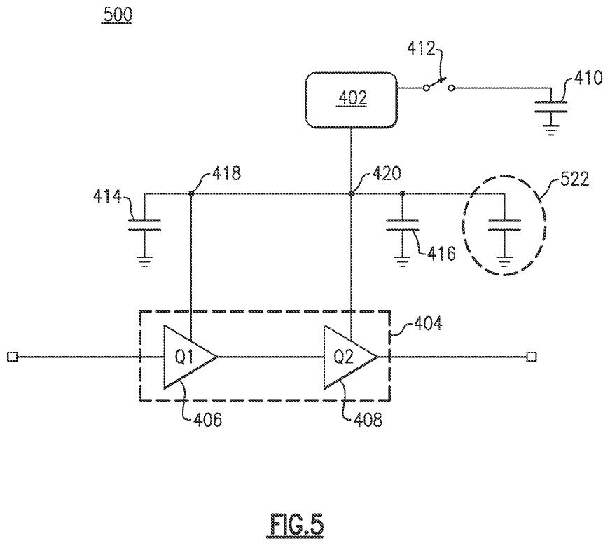

FIG. 5 is a schematic diagram of an example of an amplifier circuit assembly 500 with an additional capacitor 522. Apart from the additional capacitor 522, the elements of the amplifier circuit assembly 500 may be identical to that of amplifier circuit assembly 400 shown in FIG. 4.

The amplifier circuit assembly 500 may include an additional capacitor 522 disposed between the second supply node 420 and a ground. The additional capacitor 522 may be connected to the second capacitor 416 in parallel. In this example, the capacitance at the second supply node 420 may be increased.

These solutions have provided some additional bandwidth, but generally compromised system ET performance in order to guarantee that the PA performance would be stable and meet linearity requirements while operating in APT mode. This trade-off is generally accomplished by adjusting the Vcc decoupling capacitance such that it is large enough to stabilize the PA and provide good APT linearity and yet small enough to not cause ET degradation due to the ET modulator driving too high of a load capacitance. Higher load capacitance can reduce the slew-rate/bandwidth of the ET modulator and can limit the achievable efficiency and system bandwidth. This can make it difficult to support the wide bandwidth modulations used in 5G NR radios while operating in ET mode.

More recently designs are starting to use a near PA Vcc de-coupling capacitor which can be switched in/out of circuit depending on whether ET or APT operation is desired.

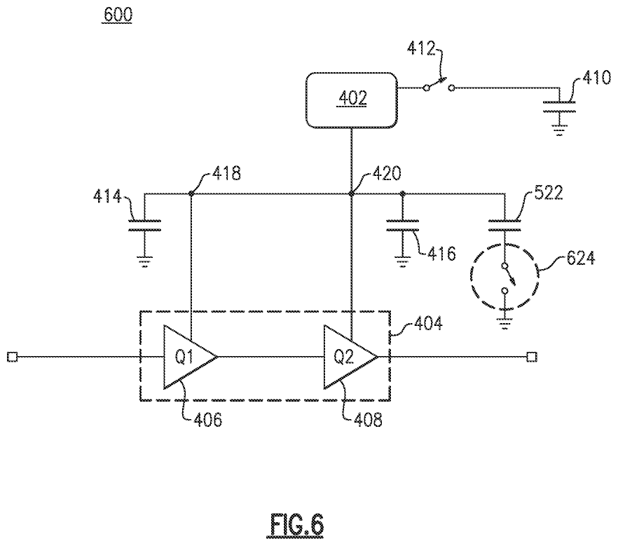

FIG. 6 is a schematic diagram of an example of an amplifier circuit assembly 600 with a capacitor switch 624. Apart from the capacitor switch 624, the elements of the amplifier circuit assembly 600 may be identical to that of amplifier circuit assembly 500 shown in FIG. 5.

The amplifier circuit assembly 600 may further include a capacitor switch 624 disposed between an additional capacitor 522 and the ground. Therefore, the capacitor switch 624 may be controlled to be closed or opened depending on the operation mode of the cascade amplifier module 404, particularly the second amplifier stage 408.

For ET mode, the capacitor switch 624 may be opened and the ET modulator may provide the broadband low impedance needed by the second amplifier stage 408 and the amplifier circuit assembly 600 may provide the low capacitance load desired by the ET modulator. In APT mode, the capacitor switch 624 may be closed and the capacitance at the second supply node 420 may provide the wide bandwidth low impedance required by the amplifier circuit assembly 600 while not limiting the APT source. This allows for improved APT and ET bandwidth operation, but provides little to none benefit on Q1 stability or supply flexibility if needed.

The present disclosure describes a flexible PA supply interface architecture which is configurable for either optimum APT or ET operation modes. It also provides the flexibility to support either 1-stage or 2-stage modulation in ET mode allowing further flexibility for the user and PA design. In all, the opportunity for optimum linearity performance can be achieved in APT Mode operated by a common supply, 2-Stage APT mode operated by separate supplies for each stage, 1-Stage ET mode, and 2-Stage ET mode without compromising the PA design/performance and thus providing the best solution for the user while reducing the constraints for the PA designer.

Hereafter, an amplifier circuit assembly according to an embodiment of the present disclosure is provided. According to an embodiment, the amplifier circuit assembly is a multi-switch PA supply network which can be configured for optimal APT or ET operation—thus eliminating the need to compromise the PA performance during one or both modes of operation in order to support both. The flexibility of this circuit assembly makes it easier to support wide bandwidth 5G NR waveforms in both ET and APT operating modes. The circuit assembly can be configured on-the-fly through MIPI control for optimal operation in either mode and even supports separate (Vcc1, Vcc2) or common (Vcc=Vcc1+Vcc2) collector supplies. It provides more flexibility for alternate supply connection methods than the single capacitor switch previous solution and far better opportunities for simultaneous optimization of the system in APT or ET modes.

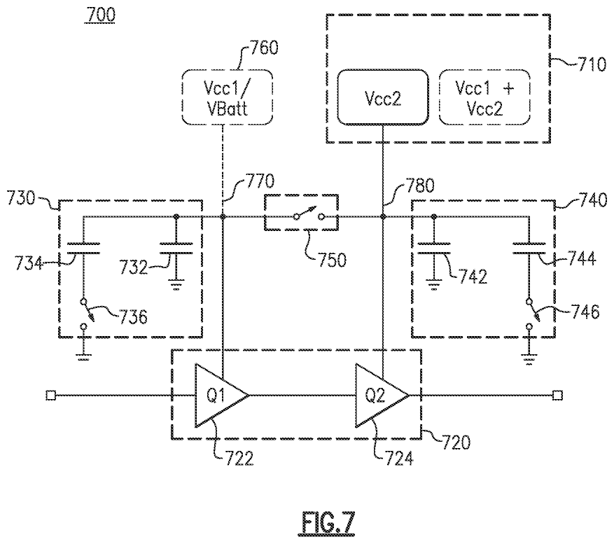

FIG. 7 is a schematic diagram of an example of an amplifier circuit assembly according to an embodiment of the present disclosure.

As shown in FIG. 7, the amplifier circuit assembly 700 includes a power supply module 710, a cascade amplifier module 720, and a switch 750.

The power supply module 710 may be configured to generate a supply voltage that changes based on a radio frequency signal. The power supply module 710 may generate an envelope tracking (ET) supply signal as the supply voltage that changes in relation to an envelope of the radio frequency signal. The power supply module 710 may also generate an average power tracking (APT) supply signal as the supply voltage that changes in relation to the average power signal in a predetermined period.

According to an embodiment, the power supply module 710 may be configured to provide common supply voltage (Vcc1+Vcc2) that is applicable to both the first amplifier stage 722 and the second amplifier stage 724, or to provide a supply voltage (Vcc2) that is applicable to the second amplifier stage 724.

The cascade amplifier module 720 may be configured to amplify the radio frequency signal when powered at least by the supply voltage. The cascade amplifier module may comprise a first amplifier stage 722 and a second amplifier stage 724. According to an embodiment, the second amplifier stage 724 may be powered by the power supply module 710. Thus, the power supply module 710 may generate the supply voltage depending on the operation mode of the second amplifier stage 724. The first amplifier stage 722 may be powered by the power supply module 710 or an additional power supply module 760 that provides a constant supply voltage.

The first amplifier stage 722 and the second amplifier stage 724 may be configured to operate in respective operation modes. According to an embodiment, each of the respective operation modes may be an average power tracking (APT) mode or an envelope tracking (ET) mode. The operating modes of the first amplifier stage 722 and the second amplifier stage 724 may be same or different from each other.

The first amplifier stage 722 may have a first supply node 770 floated from a ground by a first adjustable capacitance 730. The first supply node 770 may be configured to receive a supply voltage for the first amplifier stage 722. The first adjustable capacitance 730 may be a capacitance value defined by a first default capacitor 732 and an additional capacitor 734, as will be described later. The first adjustable capacitance 730 may be controlled to have different capacitance value depending on the operating mode of the first amplifier stage 722. For example, the first adjustable capacitance 730 may be adjusted to be reduced capacitance when the first amplifier stage 722 is operating in the ET mode. The reduced capacitance may provide the wider bandwidth low impedance required by the cascaded amplifier module 720.

According to an embodiment of the present disclosure, the first supply node 770 may be connected to the ground via a first default capacitor 732 connected to an additional capacitor 734 in parallel. The first adjustable capacitance 730 may be adjusted by switching a first capacitor switch 736 disposed between the additional capacitor 734 and the ground.

The second amplifier stage 724 may have a second supply node 780 floated from the ground by a second adjustable capacitance 740. The second supply node 780 may be configured to receive a supply voltage for the second amplifier stage 724. That is, the supply voltage provided by the power supply module 710 may be applied to the second amplifier stage 724 via the second supply node 780.

The second adjustable capacitance 740 may be controlled to have different capacitance value depending on the operating mode of the second amplifier stage 724. The second adjustable capacitance 740 may be a capacitance value defined by a second default capacitor 742 and an additional capacitor 744, as will be described later. For example, the second adjustable capacitance 740 may be adjusted to be reduced capacitance when the second amplifier stage 724 is operating in the ET mode. The reduced capacitance may provide the wider bandwidth low impedance required by the cascaded amplifier module 720.

According to an embodiment of the present disclosure, the second supply node 780 may be connected to the ground via a second default capacitor 742 connected to an additional capacitor 744 in parallel. The second adjustable capacitance 740 may be adjusted by switching a second capacitor switch 746 disposed between the additional capacitor 744 and the ground.

The switch 750 may be configured to connect or disconnect the first supply node 770 and the second supply node 780 depending on the respective operation modes of the first amplifier stage 722 and the second amplifier stage 724. According to an embodiment of the present disclosure, the switch 750 may be configured to be closed when the first amplifier stage 722 and the second amplifier stage 724 are operating in a same operation mode, for example, both the first and second amplifier stages 722, 724 operating in ET modes, or both the first and second amplifier stages 772, 724 operating in APT modes. In case the switch 750 is closed, the first supply node 770 and the second supply node 780 may be electrically connected to each other. That is, when the switch is closed, the supply voltage provided by the power supply module 710 may be applied not only to the second supply node 770 but also to the first supply node 780.

According to an embodiment, the switch 750 may be opened when the first amplifier stage 722 and the second amplifier stage 724 are operating in different modes. For example, the first amplifier stage 722 may be operating in the APT mode, and the second amplifier 724 may be operating in ET mode, and the power supply module 710 may provide an ET signal to the second amplifier stage 724 via the second supply node 780. In this example, the amplifier circuit assembly 700 may further include an additional power supply 760 that is configured to provide a constant supply voltage to the first amplifier stage 722 via the first supply node 770.

According to an embodiment, the switch 750 may be opened when both the first amplifier stage 722 and the second amplifier stage 724 are operating in same operating mode, while the supply voltages may be applied to the first supply node 770 and the second supply node 780 separately. For example, the switch 750 may be opened when both the first amplifier stage 722 and the second amplifier stage 724 are operating in APT mode, and each of the first amplifier stage 722 and the second amplifier stage 724 are controlled separately.

FIGS. 8A-8C shows waveforms for power amplifiers operating in a fixed supply voltage mode, an average power tracking (APT) mode, and an envelope tracking (ET) mode, respectively.

In FIG. 8A, a graph illustrates the voltage of a RF signal 804 and a power amplifier supply voltage 802 versus time. The RF signal 804 has a signal envelope 805. It can be important that the power amplifier supply voltage 802 of the power amplifier has a voltage level greater than that of the RF signal 804. For example, providing a supply voltage to a power amplifier having a magnitude less than that of the RF signal 804 can clip the signal, thereby creating signal distortion and/or other problems. Thus, it is important the power amplifier supply voltage 802 be greater than that of the signal envelope 805. However, it can be desirable to reduce a difference in voltage between the power amplifier supply voltage 802 and the signal envelope 805 of the RF signal 804, as the area between the power amplifier supply voltage 802 and the signal envelope 805 can represent lost energy, which can reduce battery life and increase heat generated in a mobile device.

FIG. 8B is a graph illustrating a power amplifier supply voltage 808 that varies or changes in relation to the signal envelope 807 of the RF signal 810. The graph shown in FIG. 8B may correspond to an average power tracking (APT) mode of power amplifier operation. In contrast to the power amplifier supply voltage 802 of FIG. 8A, the power amplifier supply voltage 808 of FIG. 8B changes in discrete voltage increments during different time slots, delineated by the dashed lines. The amplifier supply voltage 808 during a particular time slot may be adjusted based on the average power of the envelope 807 during that time slot, for example. For instance, the slot on the right may correspond to a lower power mode of operation than the slot on the left. By lowering the supply voltage during certain time slots, APT operation can improve power efficiency as compared to the fixed supply operation shown in FIG. 8A.

In FIG. 8C, a graph illustrates the voltage of a RF signal 816 and a power amplifier supply voltage 814 versus time. The graph shown in FIG. 8C may correspond to an envelope tracking mode of power amplifier operation. In contrast to the power amplifier supply voltage 802 of FIG. 8A, the power amplifier supply voltage 814 of FIG. 8B varies or changes in relation to the signal envelope 815. The area between the power amplifier supply voltage 814 and the signal envelope 815 in FIG. 8C is less than the area between the power amplifier supply voltage 802 and the signal envelope 805 in FIG. 8A, and thus the graph of FIG. 8C can be associated with a power amplifier system having greater energy efficiency. By tracking the supply voltage to the envelope, envelope tracking operation can improve power efficiency as compared to both the fixed supply operation shown in FIG. 8A and the APT mode shown in FIG. 8B.

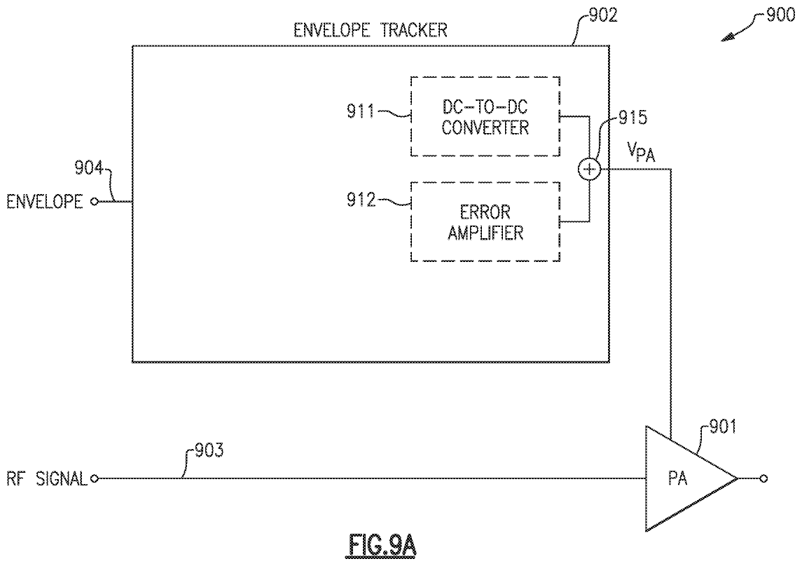

FIG. 9A is a schematic diagram of an envelope tracking system 900 according to one embodiment. The envelope tracking system 900 includes a power amplifier 901 and an envelope tracker 902. The power amplifier 901 provides amplification to a radio frequency signal 903.

The envelope tracker 902 receives an envelope signal 904 corresponding to an envelope of the radio frequency signal 903. Additionally, the envelope tracker 902 generates a power amplifier supply voltage V_{PA}, which supplies power to the power amplifier 901.

The illustrated envelope tracker 902 includes a DC-to-DC converter 911 and an error amplifier 912 that operate in combination with one another to generate the power amplifier supply voltage V P_{A} based on the envelope signal 904. In the illustrated embodiment, an output of the DC-to-DC converter 911 and an output of the error amplifier 912 are combined using a combiner 915.

The envelope tracker 902 of FIG. 9A illustrates one example of analog envelope tracking, in which a switching regulator operate in parallel with one another to track an envelope of an RF signal.

FIG. 9B is a schematic diagram of an envelope tracking system 940 according to another embodiment. The envelope tracking system 940 includes a power amplifier 901 and an envelope tracker 932. The power amplifier 901 provides amplification to a radio frequency signal 903.

The envelope tracker 932 receives an envelope signal 904 corresponding to an envelope of the radio frequency signal 903. Additionally, the envelope tracker 932 generates a power amplifier supply voltage V_{PA}, which supplies power to the power amplifier 901.

The illustrated envelope tracker 932 includes a multi-level switching circuit 935. In certain implementations, the multi-level switching circuit includes a multi-output DC-to-DC converter for generating regulated voltages of different voltage levels, switches for controlling selection of a suitable regulated voltage over time based on the envelope signal, and a filter for filtering the output of the switches to generate the power amplifier supply voltage.

The envelope tracker 932 of FIG. 9B illustrates one example of MLS envelope tracking.

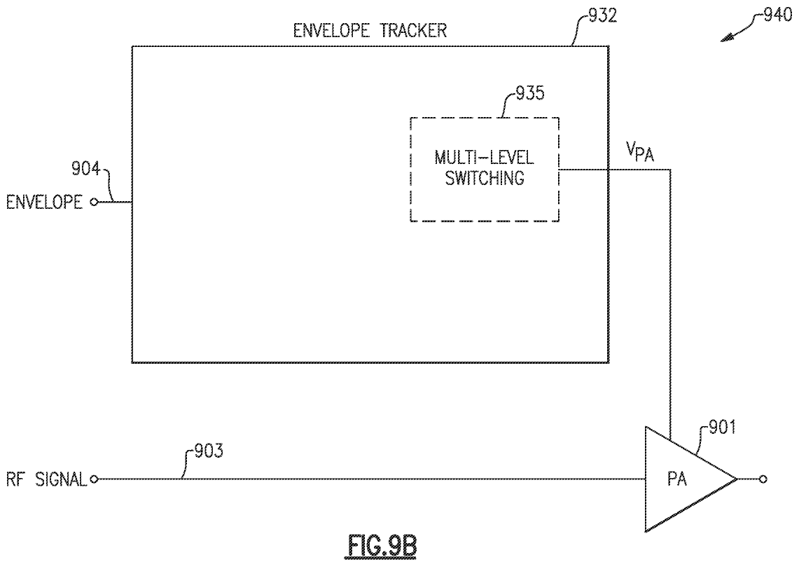

FIG. 10 is a schematic diagram of an envelope tracking system 1000 according to another embodiment. The envelope tracking system 1000 includes a power amplifier 1001 and an envelope tracker 1002. The power amplifier 1001 provides amplification to a radio frequency signal 1003.

The envelope tracker 1002 receives an envelope signal corresponding to an envelope of the radio frequency signal 1003. In this example, the envelope signal is differential. Additionally, the envelope tracker 1002 generates a power amplifier supply voltage V_{PA}, which supplies power to the power amplifier 1001.

The illustrated envelope tracker 1002 includes an envelope amplifier 1011, a first comparator 1021, a second comparator 1022, a third comparator 1023, a coding and dithering circuit 1024, a multi-output boost switcher 1025, a filter 1026, a switch bank 1027, and a capacitor bank 1030. The capacitor bank 1030 includes a first capacitor 1031, a second capacitor 1032, and a third capacitor 1033. Additionally, the switch bank 1027 includes a first switch 1041, a second switch 1042, and a third switch 1043.

The envelope amplifier 1011 amplifies the envelope signal to provide an amplified envelope signal to the first to third comparators 1021-1023. The first to third comparators 1021-1023 compare the amplified envelope signal to a first threshold T1, a second threshold T2, and a third threshold T3, respectively. The results of the comparisons are provided to the coding and dithering circuit 1024, which processes the results to control selection of switches of the switch bank 1027. The coding and dithering circuit 1024 can activate the switches while using coding and/or dithering to reduce artifacts arising from opening and closing the switches.

Although an example with three comparators is shown, more or fewer comparators can be used. Furthermore, the coding and dithering circuit 1024 can be omitted in favor of controlling the switch bank in other ways. In a first example, coding but not dithering is used. In a second example, dithering but not coding is used. In a third example, neither coding nor dithering is used.

The multi-output boost switcher 1025 generates a first regulated voltage V_{MLS1}, a second regulated voltage V_{MLS2}, and a third regulated voltage V_{MLS3} based on providing DC-to-DC conversion of a battery voltage V_{BATT}. Although an example with three regulated voltages is shown, the multi-output boost switcher 1025 can generate more or fewer regulated voltages. In certain implementations, at least a portion of the regulated voltages are boosted relative to the battery voltage V_{BATT}. In some configurations, one or more of the regulated voltages is a buck voltage having a voltage lower than the battery voltage V_{BATT}.

The capacitor bank 1030 aids in stabilizing the regulated voltages generated by the multi-output boost switcher 1025. For example, the capacitors 1031-1033 operate as decoupling capacitors.

The filter 1026 processes the output of the switch bank 1027 to generate the power amplifier supply voltage V_{PA}. By controlling the selection of the switches 1041-1043 over time based on the envelope signal, the power amplifier supply voltage V P_{A} is generated to track the envelope signal.

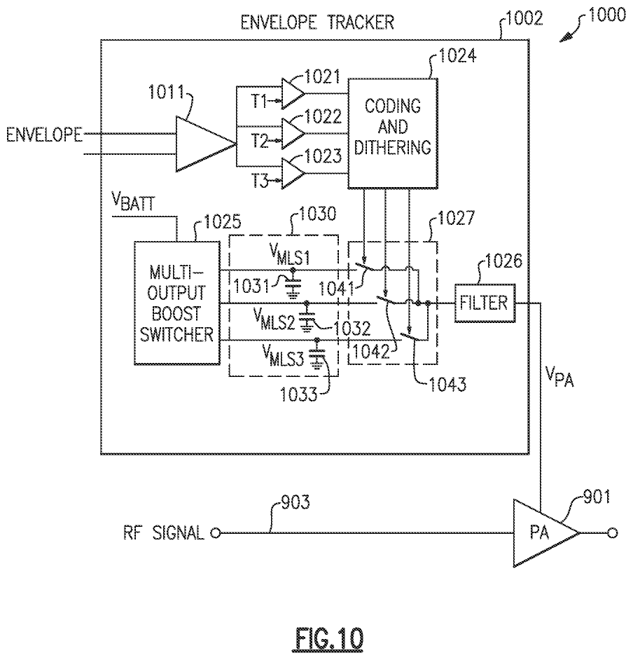

FIG. 11A is a schematic diagram of one embodiment of a packaged module 1100. FIG. 11B is a schematic diagram of a cross-section of the packaged module 1100 of FIG. 11A taken along the lines 11A-11B.

The packaged module 1100 includes an IC or die 1101, surface mount components 1103, wirebonds 1108, a package substrate 1120, and encapsulation structure 1140. The package substrate 1120 includes pads 1106 formed from conductors disposed therein. Additionally, the die 1101 includes pads 1104, and the wirebonds 1108 have been used to electrically connect the pads 1104 of the die 1101 to the pads 1106 of the package substrate 1101.

The die 1101 includes a power amplifier system, which can be implemented in accordance with any of the embodiments herein.

The packaging substrate 1120 can be configured to receive a plurality of components such as the die 1101 and the surface mount components 1103, which can include, for example, surface mount capacitors and/or inductors.

As shown in FIG. 11B, the packaged module 1100 is shown to include a plurality of contact pads 1132 disposed on the side of the packaged module 1100 opposite the side used to mount the die 1101. Configuring the packaged module 1100 in this manner can aid in connecting the packaged module 1100 to a circuit board such as a phone board of a wireless device. The example contact pads 1132 can be configured to provide RF signals, bias signals, power low voltage(s) and/or power high voltage(s) to the die 1101 and/or the surface mount components 1103. As shown in FIG. 11B, the electrically connections between the contact pads 1132 and the die 1101 can be facilitated by connections 1133 through the package substrate 1120. The connections 1133 can represent electrical paths formed through the package substrate 1120, such as connections associated with vias and conductors of a multilayer laminated package substrate.

In some embodiments, the packaged module 1100 can also include one or more packaging structures to, for example, provide protection and/or facilitate handling of the packaged module 1100. Such a packaging structure can include overmold or encapsulation structure 1140 formed over the packaging substrate 1120 and the components and die(s) disposed thereon.

It will be understood that although the packaged module 1100 is described in the context of electrical connections based on wirebonds, one or more features of the present disclosure can also be implemented in other packaging configurations, including, for example, flip-chip configurations.

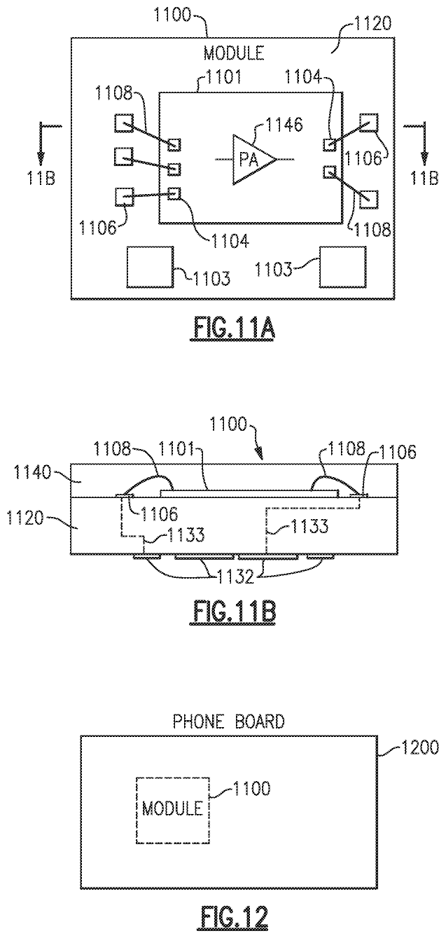

FIG. 12 is a schematic diagram of one embodiment of a phone board 1200. The phone board 1200 includes the module 1100 shown in FIGS. 11A-11B attached thereto. Although not illustrated in FIG. 12 for clarity, the phone board 1200 can include additional components and structures.

### Applications

Some of the embodiments described above have provided examples in connection with wireless devices or mobile phones. However, the principles and advantages of the embodiments can be used for any other systems or apparatus that have needs for power amplifiers.

Such amplifier circuit assemblies can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An amplifier circuit assembly comprising:
a power supply module configured to generate a supply voltage that changes based on a radio frequency signal;
a cascade amplifier module configured to amplify the radio frequency signal when powered at least by the supply voltage, the cascade amplifier module including a first amplifier stage and a second amplifier stage configured to operate in respective operation modes, the first amplifier stage having a first supply node floated from a ground by a first adjustable capacitance, the second amplifier stage having a second supply node floated from the ground by a second adjustable capacitance, the supply voltage being applied to the second supply node; and
a switch configured to connect or disconnect the first supply node and the second supply node depending on the respective operation modes of the first amplifier stage and the second amplifier stage.

2. The amplifier circuit assembly of claim 1 wherein each of the respective operation modes is an average power tracking mode or an envelope tracking mode.

3. The amplifier circuit assembly of claim 1 wherein the power supply module is configured to generate the supply voltage depending on an operation mode of the second amplifier stage.

4. The amplifier circuit assembly of claim 1 wherein the switch is configured to be closed when the first amplifier stage and the second amplifier stage are operating in a same operation mode such that the supply voltage is applied to the first supply node.

5. The amplifier circuit assembly of claim 1 wherein the switch is configured to be opened when the first amplifier stage and the second amplifier stage are operating in different operation modes or when the first amplifier stage and the second amplifier stage are operating in a same operation mode separately.

6. The amplifier circuit assembly of claim 5 further comprising an additional power supply that is configured to provide a constant supply voltage to the first supply node.

7. The amplifier circuit assembly of claim 2 wherein the first adjustable capacitance is adjusted to be reduced when the first amplifier stage is operating in the envelope tracking mode.

8. The amplifier circuit assembly of claim 7 wherein the first supply node is connected to the ground via a first default capacitor connected to an additional capacitor in parallel, and the first adjustable capacitance is adjusted by switching a first capacitor switch disposed between the additional capacitor and the ground.

9. The amplifier circuit assembly of claim 2 wherein the second adjustable capacitance is adjusted to be reduced when the second amplifier stage is operating in the envelope tracking mode.

10. The amplifier circuit assembly of claim 9 wherein the second supply node is connected to the ground via a second default capacitor connected to an additional capacitor in parallel, and the second adjustable capacitance is adjusted by switching a second capacitor switch disposed between the additional capacitor and the ground.

11. A radio frequency module comprising:
a packaging substrate configured to receive a plurality of components; and
an amplifier circuit assembly implemented on the packaging substrate, the amplifier circuit assembly including a power supply module configured to generate a supply voltage that changes based on a radio frequency signal, a cascade amplifier module configured to amplify the radio frequency signal when powered at least by the supply voltage, the cascade amplifier module including a first amplifier stage and a second amplifier stage configured to operate in respective operation modes, the first amplifier stage having a first supply node floated from a ground by a first adjustable capacitance, the second amplifier stage having a second supply node floated from the ground by a second adjustable capacitance, the supply voltage being applied to the second supply node, and a switch configured to connect or disconnect the first supply node and the second supply node depending on the respective operation modes of the first amplifier stage and the second amplifier stage.

12. The radio frequency module of claim 11 wherein the radio frequency module is a front-end module.

13. The radio frequency module of claim 11 wherein each of the respective operation modes is an average power tracking mode or an envelope tracking mode.

14. The radio frequency module of claim 11 wherein the power supply module is configured to generate the supply voltage depending on an operation mode of the second amplifier stage.

15. The radio frequency module of claim 11 wherein the switch is configured to be closed when the first amplifier stage and the second amplifier stage are operating in a same operation mode such that the supply voltage is applied to the first supply node.

16. The radio frequency module of claim 11 wherein the switch is configured to be opened when the first amplifier stage and the second amplifier stage are operating in different operation modes or when the first amplifier stage and the second amplifier stage are operating in a same operation mode separately.

17. The radio frequency module of claim 16 further comprising an additional power supply that is configured to provide a constant supply voltage to the first supply node.

18. The radio frequency module of claim 13 wherein the first adjustable capacitance is adjusted to be reduced when the first amplifier stage is operating in the envelope tracking mode.

19. A mobile device comprising:
a transceiver configured to generate a radio frequency signal; and
a front end system including an amplifier circuit assembly, the amplifier circuit assembly including a power supply module configured to generate a supply voltage that changes based on the radio frequency signal, a cascade amplifier module configured to amplify the radio frequency signal when powered at least by the supply voltage, the cascade amplifier module including a first amplifier stage and a second amplifier stage configured to operate in respective operation modes, the first amplifier stage having a first supply node floated from a ground by a first adjustable capacitance, the second amplifier stage having a second supply node floated from the ground by a second adjustable capacitance, the supply voltage being applied to the second supply node, and a switch configured to connect or disconnect the first supply node and the second supply node depending on the respective operation modes of the first amplifier stage and the second amplifier stage.

20. The mobile device of claim 19 wherein each of the respective operation modes is an average power tracking mode or an envelope tracking mode.
